(19) United States
(12) Patent Application Publication
(10) Pub. No.: US 2025/0201566 A1
(43) Pub. Date: Jun. 19, 2025

(54) METHOD FOR MANUFACTURING SEMICONDUCTOR APPARATUS AND SEMICONDUCTOR APPARATUS

(71) Applicant: Mitsubishi Electric Corporation, Tokyo (JP)

(72) Inventors: Kyohei AKIYOSHI, Tokyo (JP); Takanori TANAKA, Tokyo (JP); Tadasuke MATSUYAMA, Tokyo (JP)

(73) Assignee: Mitsubishi Electric Corporation, Tokyo (JP)

(21) Appl. No.: 18/801,517

(22) Filed: Aug. 12, 2024

(30) Foreign Application Priority Data
Dec. 18, 2023 (JP) 2023-213137

(51) Int. Cl. H01L 21/304; H01L 21/306; H01L 23/00; H01L 29/06

(52) U.S. Cl. CPC H01L 21/304; H01L 21/30625; H01L 24/32; H01L 24/83; H10D 62/117; H01L 2224/32145; H01L 2224/83

(57) ABSTRACT

According to the present disclosure, a method for manufacturing a semiconductor apparatus includes 5 steps. First step is forming a semiconductor device structure. Second step is grinding a peripheral portion, partway in a thickness direction. Third step is dividing the wafer in a direction perpendicular to the thickness direction at a position closer than a depth to which the peripheral portion of the wafer is ground, and dividing a first divided wafer which does not include the semiconductor device structure from the wafer. Fourth step is grinding a peripheral portion of a divided surface of the first divided wafer. And fifth step is forming a semiconductor device structure on the divided surface of the first divided wafer, the peripheral portion of the divided surface of which is ground.

### BACKGROUND OF THE INVENTION

### Field

The present disclosure relates to a method for manufacturing a semiconductor apparatus and a semiconductor apparatus.

### Background

JP 2021-52178 A discloses a technique for reducing substrate costs by using a thinly sliced wafer as a base for epitaxial growth.

The above-described method, however, requires beveling on a wafer before slicing. Beveling reduces a wafer diameter, which may prevent transportation and processing using the same equipment as for a wafer before the working or create the need to adjust the equipment such that the equipment can handle a change in wafer diameter.

### SUMMARY

In view of the above-described problems, an object of the present disclosure is to provide a method for manufacturing a semiconductor apparatus and a semiconductor apparatus capable of transportation and processing using the same equipment as for a wafer before working by curbing reduction in wafer diameter.

The features and advantages of the present disclosure may be summarized as follows.

A method for manufacturing a semiconductor apparatus according to the present disclosure includes: a step of forming a semiconductor device structure at a second principal surface of a wafer having a first principal surface and the second principal surface which are opposite from each other; a step of grinding a peripheral portion of the second principal surface of the wafer, at which the semiconductor device structure is formed, partway in a thickness direction from the second principal surface toward the first principal surface; a step of dividing the wafer in a direction perpendicular to the thickness direction at a position closer to the second principal surface than a depth to which the peripheral portion of the wafer is ground, and dividing a first divided wafer which does not include the semiconductor device structure from the wafer; a step of grinding a peripheral portion of a divided surface of the first divided wafer; and a step of forming a semiconductor device structure on the divided surface of the first divided wafer, the peripheral portion of the divided surface of which is ground.

Other and further objects, features and advantages of the disclosure will appear more fully from the following description.

### BRIEF DESCRIPTION OF DRAWINGS

FIG. 1 is a view showing a semiconductor apparatus according to the first embodiment of the present disclosure.

FIG. 2 is a view showing a grinding step according to the first embodiment of the present disclosure.

FIG. 3 is a view showing a division step according to the first embodiment of the present disclosure.

FIG. 4 is a view showing a bonding step according to the first embodiment of the present disclosure.

FIG. 5 is an enlarged view showing the bonding step according to the first embodiment of the present disclosure.

FIG. 6 is a view showing a beveling step according to the first embodiment of the present disclosure.

FIG. 7 is a view showing a device formation process according to the first embodiment of the present disclosure.

FIG. 8 is a view showing a semiconductor apparatus according to a first comparative example.

FIG. 9 is a view showing a division step according to the first comparative example.

FIG. 10 is a view showing a beveling step according to a second comparative example.

FIG. 11 is a view showing a division step according to the second comparative example.

FIG. 12 is a view showing a modification of the grinding step according to the first embodiment of the present disclosure.

FIG. 13 is a view showing a first modification of the bonding step according to the first embodiment of the present disclosure.

FIG. 14 is a view showing a second modification of the bonding step according to the first embodiment of the present disclosure.

FIG. 15 is a view showing a modification of the beveling step according to the first embodiment of the present disclosure.

FIG. 16 is a view showing a thickening step according to a second embodiment of the present disclosure.

FIG. 17 is a view showing a beveling step according to the second embodiment of the present disclosure.

FIG. 18 is a view showing a device formation step according to the second embodiment of the present disclosure.

FIG. 19 is a view showing a modification of the beveling step according to the second embodiment of the present disclosure.

FIG. 20 is a view showing a beveling step according to a third embodiment of the present disclosure.

FIG. 21 is a view showing a device formation process according to the third embodiment of the present disclosure.

FIG. 22 is a view showing a modification of the beveling step according to the third embodiment of the present disclosure.

FIG. 23 is a view showing a grinding step to be performed by an equipment formed by attaching a grinding stone to a rotary edging machine.

FIG. 24 is a view showing a kerf loss which accompanies the grinding step in FIG. 23.

### DESCRIPTION OF EMBODIMENTS

### First Embodiment

### [Method for Processing Semiconductor Apparatus According to First Embodiment of Present Disclosure]

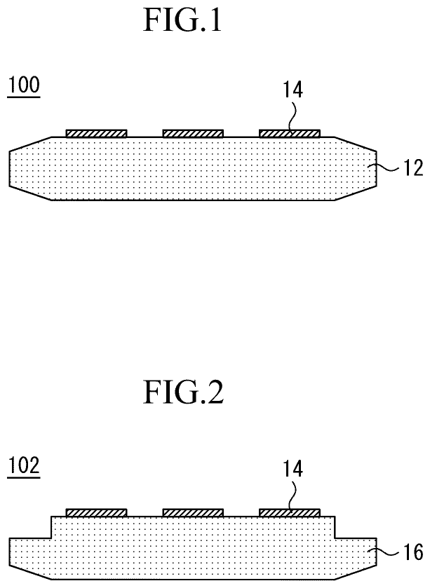

A method for processing a semiconductor apparatus according to a first embodiment of the present disclosure will be described. FIG. 1 is a view showing a semiconductor apparatus according to the first embodiment of the present disclosure. A semiconductor apparatus 100 includes a wafer 12. The wafer 12 is, for example, a single-crystal SiC wafer having a second principal surface opposite from a first principal surface. Note that the first principal surface is a wafer reverse side, and the second principal surface is a wafer obverse side.

The wafer 12 may be made of Si or may be made of a wide bandgap semiconductor having a wider bandgap than Si. The wide bandgap semiconductor is, for example, a SiC- or GaN-based material, a gallium oxide-based material, or diamond. If a switching device or a diode device is formed using a wide bandgap semiconductor, voltage resistance and an allowable current density can be enhanced. This allows size reduction.

An aspect of the present disclosure is cost-effective and is particularly beneficial to a semiconductor apparatus using a wafer which is not easily available. A particularly beneficial example is a case where the wafer 12 is made of SiC. SiC wafers are harder to increase in diameter, are more expensive, and are lower in yields due to crystal defects than Si wafers. That is, there is a problem that SiC wafers are not cost-effective.

A single SiC crystal is generally produced by a sublimation method. In the sublimation method, a temperature difference in a crystal increases with increase in wafer diameter to increase crystal defects. That is, there is a problem that SiC wafers suffer reduction in availability of substrates with less crystal defects with increase in wafer diameter.

The above-described problems with SiC wafers can be simultaneously solved by reclaiming a SiC wafer with less crystal defects.

An epitaxial film is formed at the second principal surface of the wafer 12. A semiconductor device structure 14 is formed on the epitaxial film. The semiconductor device structure 14 is, for example, a power device structure, such as a MOSFET, a diode, or an IGBT. The formation of the semiconductor device structure 14 includes ion implantation and surface electrode formation. Note that the semiconductor device structure 14 is formed inside an outermost peripheral portion of the wafer 12 which is tapered.

Note that if the wafer 12 is made of GaN, the semiconductor device structure 14 is, for example, a GaN radio-frequency device structure. Alternatively, a GaN radio-frequency device structure may be formed on the wafer 12 made of SiC.

FIG. 2 is a view showing a grinding step according to the first embodiment of the present disclosure. In the grinding step of the present embodiment, a peripheral portion of the second principal surface of the wafer 12 is ground partway in a thickness direction from the second principal surface toward the first principal surface, thereby forming a wafer 16 having a convex structure in cross-section. This results in formation of a semiconductor apparatus 102 in which the semiconductor device structure 14 protrudes from the peripheral portion.

The grinding step can be performed by, for example, an equipment formed by attaching a grinding stone to a rotary edging machine. As the grinding stone, one which is adjusted so as to be capable of forming a wafer into an arbitrary shape by grinding a periphery of the wafer is used. The grinding step may be performed by cutting a periphery partway by a dicing equipment.

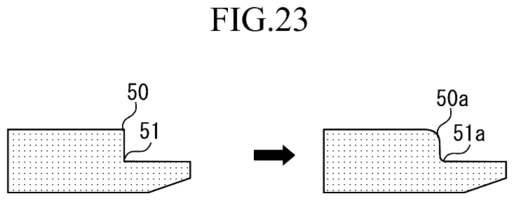

FIG. 23 is a view showing a grinding step to be performed by an equipment formed by attaching a grinding stone to a rotary edging machine. A view on the left in FIG. 23 shows a wafer after grinding using a new grinding stone immediately after replacement. A view on the right in FIG. 23 shows a wafer after grinding using a worn grinding stone. Since if a plurality of wafers are worked using the same grinding stone, the grinding stone is worn away, and expected grinding cannot be performed, a wafer shape after working is as on the right in FIG. 23. In this case, the grinding step turns corners 50 and 51 in a wafer into rounded corners 50a and 51a.

If the corner 50a has a radius of 500 μm or less, dust generation and chipping due to a knife edge (to be described later) can be reduced. If the corner 50a has a smaller radius, i.e., a radius of 300 μm or less, dust generation or chipping can be reduced to a greater extent. If the corner 50a has a radius of 100 μm or less, dust generation or chipping due to an edge shape can be largely suppressed.

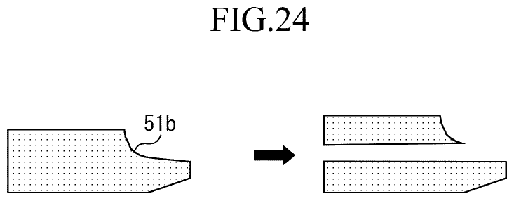

FIG. 24 is a view showing a kerf loss which accompanies the grinding step in FIG. 23. A view on the left in FIG. 24 shows a wafer before division, and a view on the right in FIG. 24 shows wafers after the division. FIG. 24 shows a kerf loss generated when the grinding steps turns the corner 51 in the view on the left in FIG. 23 into a corner 51b with a large radius.

Note that a kerf loss is a so-called material loss and refers to a portion which is removed as cuttings at the time of wafer cutting. Specifically, a portion as a boundary between the wafers after the division in the view on the right in FIG. 24 corresponds to a kerf loss.

If the corner 51b has a large radius as in the view on the left in FIG. 24, an end portion shape is sharp as in the view on the right in FIG. 24. Such a shape will hereinafter be called a knife edge. The knife edge causes chipping and dust generation.

Chipping and dust generation due to a knife edge is suppressed to a greater extent if a kerf loss generated at the time of division is larger. That is, even if the corner 51b has a large radius, fears of chipping and dust generation are reduced. For example, if a kerf loss at the time of division is more than 100 μm, a radius of 200 μm or less is tolerated. If the kerf loss is smaller and is 100 μm to 80 μm, a radius of 150 μm or less is tolerated. If the kerf loss is much smaller and is 60 μm or less, a radius of 100 μm or less is tolerated. Note that if one of divided wafers is worked and reused to form a device again, a kerf loss and the radius of the corner 51b are preferably small.

Additionally, if an angle of a terrace is 45 degrees to 135 degrees, dust generation or chipping due to a knife edge can be reduced. If the angle is 60 degrees to less than 120 degrees, dust generation or chipping can be reduced to a greater extent. If the angle is 75 degrees to less than 105 degrees, dust generation or chipping due to an edge shape can be largely suppressed.

Note that a width for working is preferably small in the grinding step. This is because if a width for grinding is large, a region with a small substrate thickness is large at a peripheral portion of the wafer 16 to easily cause chipping and cracks. It is known that chipping and cracks often occur if the width for grinding is 10 mm or more. For this reason, the width for grinding is preferably less than 10 mm. A smaller width, such as a width less than 5 mm, 3 mm, or 1 mm, is more preferable.

The grinding step is preferably performed only to a depth which leaves a substrate thickness of 100 μm or more. This allows suppression of fractures and chips which occur at an end portion of a wafer to be reused after a division step (to be described later).

Additionally, the grinding step may be performed before formation of the epitaxial film that is performed before formation of the semiconductor device structure 14 or performed after formation of the epitaxial film. The grinding step is performed outside the semiconductor device structure 14 so as not to damage the semiconductor device structure 14.

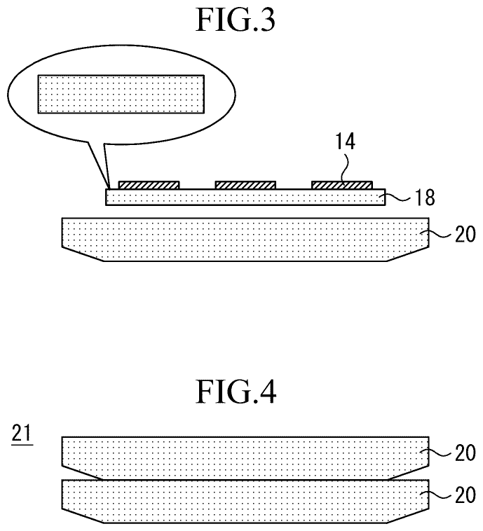

FIG. 3 is a view showing a division step according to the first embodiment of the present disclosure. In the division step of the present embodiment, the wafer 16 is divided in a direction perpendicular to the thickness direction at a position closer to the second principal surface than a depth to which the peripheral portion in the wafer 12 is ground. With this division, the semiconductor apparatus 102 is divided into a divided wafer 18 which includes the semiconductor device structure 14 and a divided wafer 20 which does not include the semiconductor device structure 14. That is, the divided wafer 20 not including the semiconductor device structure 14 is divided from the wafer 16.

At that time, a peripheral portion of the divided wafer 18 does not become a knife edge. This is because an outermost peripheral portion which can become a knife edge is eliminated in advance by performing the grinding step shown in FIG. 2. This results in advancement of a process of manufacturing a semiconductor apparatus without dust generation or chipping in the divided wafer 18.

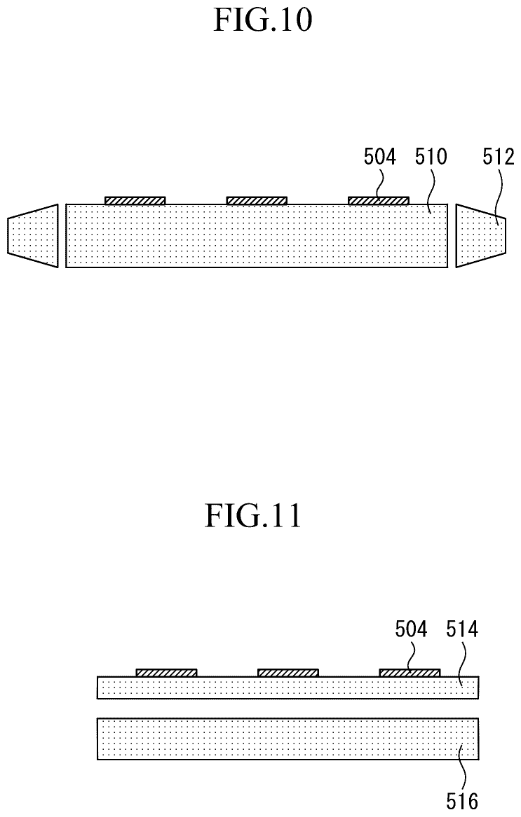

Additionally, a wafer diameter of the divided wafer 20 is the same as a wafer diameter of the original wafer 12. This is because the grinding step of the present embodiment does not eliminate an outermost peripheral portion, unlike a beveling step (to be described later with reference to FIG. 10). That is, curbing of reduction in wafer diameter allows transportation and processing using the same equipment as for a wafer before working.

Note that a method for dividing the wafer may be a method which involves contact with a dicing saw or the like or a non-contact method using laser or the like. For example, a laser slicing technique that provides a modifying layer by laser and performs division in a direction perpendicular to a direction from a first principal surface toward a second principal surface may be used.

A substrate thickness of the divided wafer 20 is preferably 100 μm or more. This is because if the substrate thickness of the divided wafer 20 is small, a fracture may occur in succeeding steps in FIGS. 4 to 7 or transportation and processing may become hard due to large warpage.

FIG. 4 is a view showing a bonding step according to the first embodiment of the present disclosure. In the bonding step of the present embodiment, another divided wafer 20 is bonded to a first principal surface of the divided wafer 20. This results in formation of a bonded wafer 21 which has the same wafer diameter as the original wafer 12. By bonding a plurality of divided wafers 20 as described above to increase a substrate thickness, wafer warpage can be suppressed to a greater extent than in a case where the divided wafer 20 is used singly.

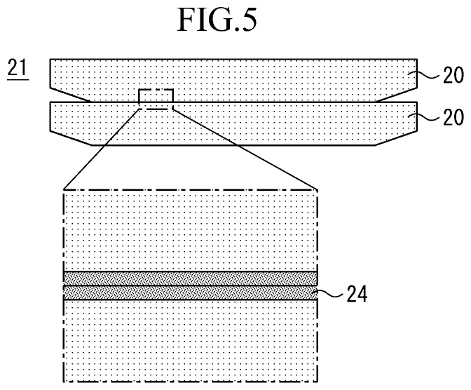

FIG. 5 is an enlarged view showing the bonding step according to the first embodiment of the present disclosure. The bonding step of the present embodiment may be performed using, for example, a technique based on room-temperature bonding. At this time, an amorphous layer 24 is formed at bonding interfaces of the bonded wafer 21.

Room-temperature bonding is a bonding method capable of obtaining a clean interface because a metal layer and the like are not included in a bonding interface. A sticking force at the time of bonding can be enhanced by performing a planarization step of planarizing at least one of the bonding interfaces by polishing before the bonding step. Note that the planarization may be performed by CMP or the like instead of polishing.

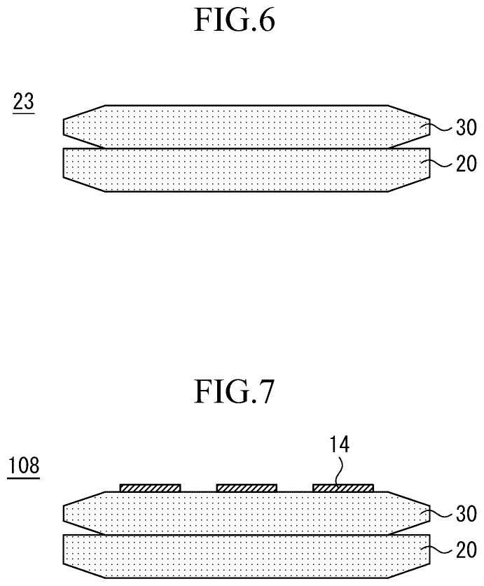

FIG. 6 is a view showing a beveling step according to the first embodiment of the present disclosure. In the beveling step of the present embodiment, a peripheral portion on a second principal surface side of the bonded wafer 21 is ground into a tapered shape. That is, a peripheral portion of a divided surface of the divided wafer 20 on the second principal surface side is ground into a tapered shape. This results in formation of a bonded wafer 23 in which a divided wafer 30, a peripheral portion on a second principal surface side of which is worked into a tapered shape and the unworked divided wafer 20 are bonded together. Since this step can bring a shape of the bonded wafer 21 close to a shape of the original wafer 12, fine adjustment for wafer alignment is unnecessary.

Fine adjustment in wafer alignment will be described in detail. In the wafer alignment, a location at which a light transmission amount is equal to or less than a threshold at the time of scanning of a wafer by laser light is recognized as a wafer end portion. If an end portion of a wafer is worked into a tapered shape, since surface roughness of a tapered portion makes light unlikely to pass through, the wafer end portion is easily recognized.

If a wafer is ground, for example, such that a cross-section has a convex structure, a wafer end portion is thinner than a wafer central portion. In this case, a light transmission amount at the wafer end portion may not be equal to or less than the threshold, and the wafer end portion may fail to be recognized.

For the above-described reason, if the wafer is processed by the same equipment as a common wafer, it is necessary to adjust the threshold for a light transmission amount on an as-needed basis or set a new threshold which allows recognition of end portions of the both wafers. That is, in either case, fine adjustment for wafer alignment is necessary. In the beveling step of the present embodiment, the peripheral portion on the second principal surface side of the bonded wafer 21 is ground into a tapered shape. The beveling step has the advantage in that such fine adjustment is unnecessary.

The bonded wafer 23 may be worked so as to have a desired substrate thickness throughout the whole by, for example, grinding, polishing, CMP, or the like. The desired substrate thickness may be, for example, the same substrate thickness as the wafer 12. With this configuration, at the time of reuse of the bonded wafer 23 as a wafer, it is possible to perform transportation and processing using the same equipment as for a wafer before working without performing adjustment involved in a difference in substrate thickness.

FIG. 7 is a view showing a device formation process according to the first embodiment of the present disclosure. In the device formation process of the present embodiment, an epitaxial film is formed on a second principal surface side of the bonded wafer 23, and the semiconductor device structure 14 is formed on the epitaxial film. That is, the semiconductor device structure 14 is formed on a divided surface of the divided wafer 30. Note that the semiconductor device structure 14 is formed inside an outermost peripheral portion of the divided wafer 30 which is tapered.

A semiconductor apparatus 108 obtained in the above-described manner has a similar function to the semiconductor apparatus 100. For this reason, the semiconductor apparatus 108 can be sequentially subjected to the steps shown in FIGS. 2 to 7, like the semiconductor apparatus 100.

As described above, the steps shown in FIGS. 2 to 7 curb reduction in a wafer diameter of a semiconductor apparatus. This allows transportation and processing using the same apparatus as for a wafer before working.

### [Method for Processing Semiconductor Apparatus According to Comparative Example]

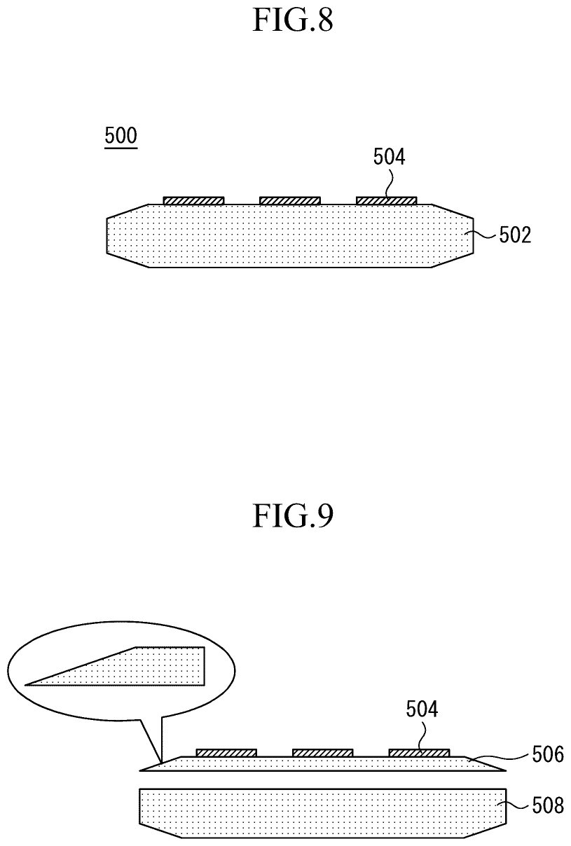

To describe effects of a semiconductor apparatus according to the present disclosure, a method for processing a semiconductor apparatus according to a comparative example will be described. FIG. 8 is a view showing a semiconductor apparatus according to a first comparative example. A semiconductor apparatus 500 includes a wafer 502 and a semiconductor device structure 504 and has a similar configuration to the semiconductor apparatus 100.

FIG. 9 is a view showing a division step according to the first comparative example. In the division step according to the first comparative example, the wafer 502 is divided in a direction perpendicular to a thickness direction. With this division, the semiconductor apparatus 500 is divided into a divided wafer 506 which includes the semiconductor device structure 504 and a divided wafer 508 which does not include the semiconductor device structure 504.

At that time, a peripheral portion of the divided wafer 506 becomes a thin and sharp knife edge. If a process of manufacturing a semiconductor apparatus is advanced using a wafer, a peripheral portion of which is a knife edge, a carrier which stores wafers may be shaved to generate dust or chipping may occur. For this reason, to perform a wafer division step, working which prevents a peripheral portion from becoming a knife edge is necessary.

FIG. 10 is a view showing a beveling step according to a second comparative example. In the second comparative example, the beveling step is performed on a semiconductor apparatus 500 having a similar configuration to that in the first comparative example before a division step.

In the beveling step according to the second comparative example, a peripheral portion of a wafer 502 is ground such that the peripheral portion is penetrated in a thickness direction. That is, an outermost peripheral portion of the wafer 502 is eliminated. This results in production of a divided wafer 510 which includes a semiconductor device structure 504 and a wafer peripheral portion 512 which does not include the semiconductor device structure 504.

FIG. 11 is a view showing a division step according to the second comparative example. In the division step according to the second comparative example, the divided wafer 510 is divided in a direction perpendicular to the thickness direction. With this division, the divided wafer 510 is divided into a divided wafer 514 which includes the semiconductor device structure 504 and a divided wafer 516 which does not include the semiconductor device structure 504.

At that time, a peripheral portion of the divided wafer 514 does not become a knife edge. This is because an outermost peripheral portion which can become a knife edge is eliminated in advance by performing the beveling step shown in FIG. 10. This results in advancement of a process of manufacturing a semiconductor apparatus without dust generation or chipping in the divided wafer 514.

A wafer diameter of the divided wafer 516 is smaller than a wafer diameter of the original wafer 502. This is because the outermost peripheral portion is eliminated by performing the beveling step shown in FIG. 10. This results in prevention of transportation and processing using the same equipment as for a wafer before working at the time of reuse of the divided wafer 516 or creates the need to adjust the equipment such that the equipment can handle a change in wafer diameter. The present disclosure can solve the problem.

### [Method for Processing Semiconductor Apparatus According to Modification of First Embodiment of Present Disclosure]

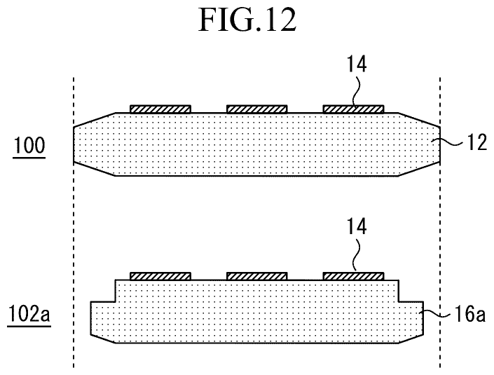

Processing methods according to modifications of the present embodiment will hereinafter be illustrated. FIG. 12 is a view showing a modification of the grinding step according to the first embodiment of the present disclosure. A grinding step of the modification is different from the grinding step in FIG. 2 in that the grinding step further includes a step of grinding the whole of a peripheral portion of a wafer.

An upper view in FIG. 12 is a view showing the semiconductor apparatus 100 before the grinding step. A lower view in FIG. 12 is a view showing a semiconductor apparatus 102a after the grinding step. The grinding step of the modification includes a process of grinding the whole of an outermost peripheral portion of a wafer in addition to the grinding step of the first embodiment. For this reason, a wafer diameter of a wafer 16a after the grinding step is smaller than the wafer diameter of the wafer 12.

Since an end portion on the reverse side of the wafer 16 is tapered, a substrate thickness is smaller toward the end portion. This may result in occurrence of a fracture and a chip at the end portion on the reverse side of the wafer 16. The grinding step of the modification has the effect of suppressing fractures and chips at an end portion by grinding a peripheral portion on the reverse side of the wafer 16a.

Note that it is preferable in the grinding step of the modification that a width for grinding the whole of an outermost peripheral portion of a wafer, i.e., a reduction in wafer diameter be small. This is because if a width for working is large, a wafer diameter of a wafer to be reused in the future is small, which may prevent transportation and processing at the time of formation of a device structure.

If a reduction in wafer diameter is less than 1 mm, the reduction can be handled with equipment adjustment or a jig change. If the reduction in wafer diameter is less than 0.8 mm, more equipment can handle the reduction even without equipment adjustment or a jig change. If the reduction in wafer diameter is less than 0.5 mm, much more equipment can handle the reduction even without equipment adjustment or a jig change. From the foregoing, a width for grinding the whole of a peripheral portion of a wafer is preferably less than 1 mm, more preferably less than 0.8 mm, and further preferably less than 0.5 mm.

The width for grinding the whole of an outermost peripheral portion of a wafer in the grinding step of the modification is much smaller than a width for working a peripheral portion in the beveling step according to the second comparative example. This is because an object of the beveling step according to the second comparative example can be accomplished by formation of a convex structure in the grinding step of the modification. Thus, the grinding step of the modification has the effect of curbing reduction in wafer diameter as compared with the comparative example.

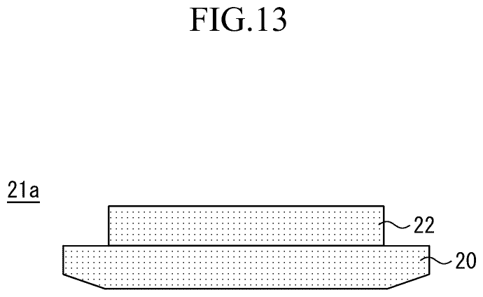

FIG. 13 is a view showing a first modification of the bonding step according to the first embodiment of the present disclosure. In a bonding step of the first modification, the divided wafer 20 and a divided wafer 22 which is smaller in wafer diameter than the divided wafer 20 are bonded together. This results in formation of a bonded wafer 21a having a convex structure in cross-section. The formation of a bonded wafer having a convex structure allows omission of a beveling step to be performed subsequently in addition to suppression of wafer warpage.

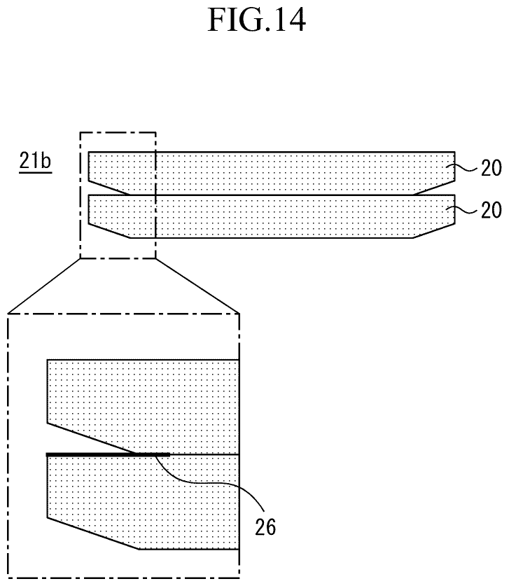

FIG. 14 is a view showing a second modification of the bonding step according to the first embodiment of the present disclosure. A bonding step of the second modification is different from the first embodiment in a planarization process to be performed before bonding. Specifically, polishing at a peripheral portion of a bonding interface is performed to a greater extent than polishing at a central portion of the bonding interface. As a result, a peripheral portion of a wafer becomes thinner than a central portion, and an unbonded region 26 is formed at a peripheral portion of a bonding interface of a bonded wafer 21b.

A substrate thickness of each of divided wafers bonded together can be measured by measuring the unbonded region 26 with, for example, a light-interference wafer thickness gauge. That is, a depth of a bonding interface which the bonded wafer 21b has can be detected in advance.

For example, if a wafer which has undergone a division step and a bonding step a plurality of times is used, a bonding interface may be present near the semiconductor device structure 14 that a finished semiconductor apparatus has. In this case, the finished semiconductor apparatus may suffer poor characteristics and reliability deterioration. The present modification can detect in advance a bonding interface present near the semiconductor device structure 14. For this reason, the above-described problem can be avoided by grinding and removing a bonding interface in question.

Note that moisture soaks into the above-described unbonded region in a subsequent wet etching step. The moisture cannot be removed by spin drying which is to be performed as processing subsequent to the wet etching step and may cause a problem in subsequent manufacturing steps. If the unbonded region is 1 mm or less wide from a periphery, the amount of moisture which soaks is negligible. For this reason, the unbonded region is preferably 1 mm or less wide from the periphery of the bonded wafer 21b.

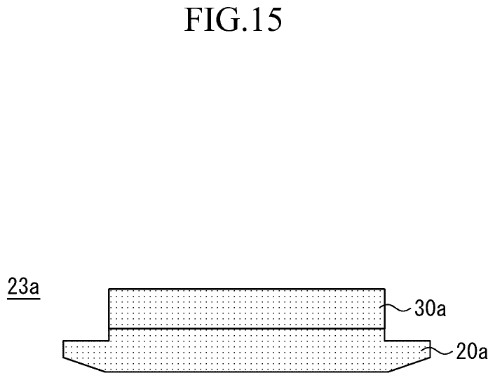

FIG. 15 is a view showing a modification of the beveling step according to the first embodiment of the present disclosure. A beveling step of the modification works the peripheral portion on the second principal surface side of the bonded wafer 21 such that a cross-section has a convex structure. This results in formation of a bonded wafer 23a in which a divided wafer 30a, an inner diameter of which is reduced by uniform grinding of a peripheral portion, and a divided wafer 20a, a cross-section of which is made to have a convex structure by uniform grinding of a peripheral portion to a fixed depth, are bonded together. That is, an inner diameter of an upper surface of the divided wafer 20a is the same as the inner diameter of the divided wafer 30a.

The beveling step of the present modification may be performed on, for example, the bonded wafer 21b according to the second modification of the bonding step. In this case, the unbonded region 26 can be removed by the beveling step.

### Second Embodiment

### [Method for Processing Semiconductor Apparatus According to Second Embodiment of Present Disclosure]

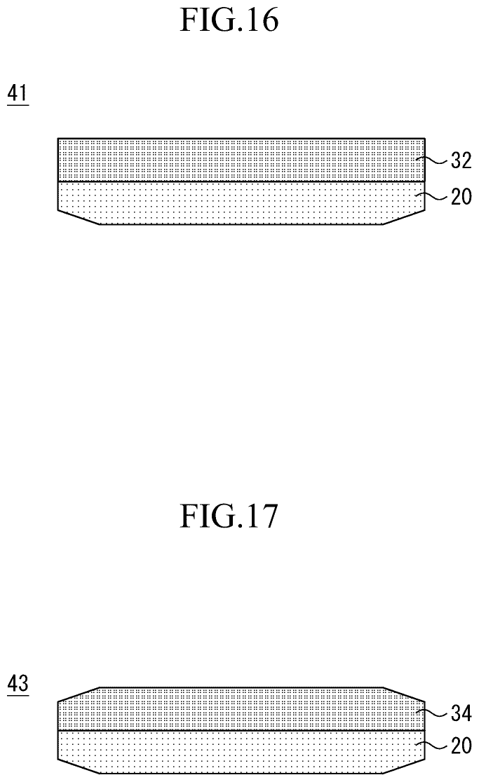

FIG. 16 is a view showing a thickening step according to a second embodiment of the present disclosure. In the first embodiment, the bonding step of bonding a plurality of divided wafers 20 is performed to suppress warpage of the divided wafer 20. In the thickening process of the present embodiment, an epitaxial film 32 is formed on a divided wafer 20. This results in formation of a thick-film wafer 41 which has the same wafer diameter as the original wafer 12. By increasing a substrate thickness as described above, wafer warpage can be suppressed to a greater extent than in a case where the divided wafer 20 is used singly. Note that the formation of the epitaxial film may be performed on either a first principal surface or a second principal surface.

A difference in specific resistance between the epitaxial film 32 and the divided wafer 20 is preferably small. This is because if the difference in specific resistance between the epitaxial film 32 and the divided wafer 20 becomes large, electric characteristics change to result in fluctuation of electric characteristics of the whole semiconductor apparatus at the time of formation of a semiconductor device structure 14 in a subsequent step.

If the above-described difference in specific resistance is 30 mΩ·m or less, fluctuations of the electric characteristics of the whole semiconductor apparatus fall within a range which allows the semiconductor apparatus to be used equally with an original semiconductor apparatus. If the above-described difference in specific resistance is 15 mΩ·m or less, fluctuations of the electric characteristics of the whole semiconductor apparatus fall within an error range. If the above-described difference in specific resistance is 6 mΩ·m or less, there are almost no fluctuations of the electric characteristics of the whole semiconductor apparatus.

From the foregoing, the difference in specific resistance between the epitaxial film 32 and the divided wafer 20 is preferably 30 m□□m or less, more preferably 15 m□□m or less, and further preferably 6 m□□m or less.

The epitaxial film 32 is preferably thick. This is because if the epitaxial film 32 is thin, the effect of suppressing warpage of the divided wafer 20 cannot be sufficiently obtained.

If a thickness of the epitaxial film 32 is 50 □m or more, warpage can be sufficiently suppressed, but an error may occur in transportation or suction in a manufacturing equipment to be used. If the thickness of the epitaxial film 32 is 100 □m or more, warpage can be sufficiently suppressed, and an error hardly occurs in transportation or suction in the manufacturing equipment to be used. If the thickness of the epitaxial film 32 is 150 □m, a semiconductor apparatus 114 has a thickness equal to that of a wafer before division, and no error occurs in transportation or suction in the manufacturing equipment to be used.

From the foregoing, the thickness of the epitaxial film 32 is preferably 50 μm or more, more preferably 100 μm or more, and further preferably 150 μm.

FIG. 17 is a view showing a beveling step according to the second embodiment of the present disclosure. In the beveling step of the present embodiment, a peripheral portion on a second principal surface side of the thick-film wafer is worked into a tapered shape. This results in obtainment of a thick-film wafer 43 in which an epitaxial film 34, a peripheral portion on a second principal surface side of which is worked into a tapered shape is formed on the unworked divided wafer 20.

The thick-film wafer 43 may be worked so as to have a desired substrate thickness by, for example, grinding, polishing, CMP, or the like. The desired substrate thickness may be, for example, the same substrate thickness as the wafer 12. With this configuration, at the time of reuse of the thick-film wafer 43 as a wafer, it is possible to perform transportation and processing using the same equipment as for a wafer before working without performing adjustment involved in a difference in substrate thickness.

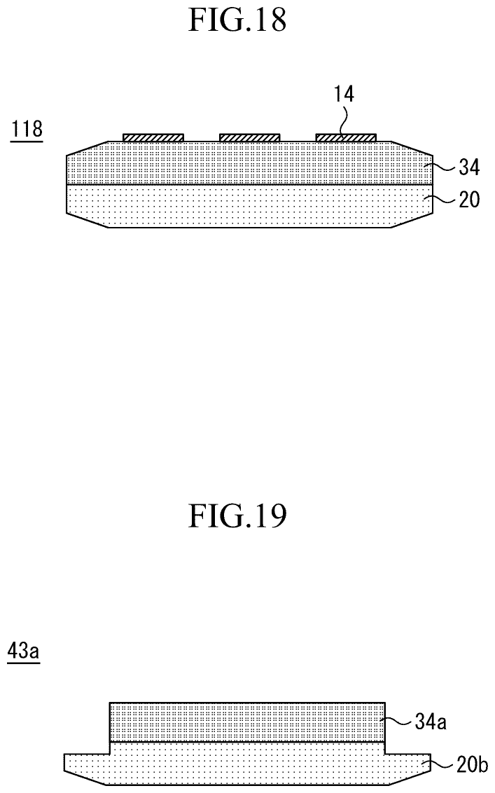

FIG. 18 is a view showing a device formation step according to the second embodiment of the present disclosure. In the device formation step of the present embodiment, an epitaxial film is formed on a second principal surface side of the thick-film wafer 43, and the semiconductor device structure 14 is formed on the epitaxial film. Note that the semiconductor device structure 14 is formed inside an outermost peripheral portion of the epitaxial film 34 which is tapered.

A semiconductor apparatus 118 obtained in the above-described manner has a similar function to the semiconductor apparatus 100. For this reason, the semiconductor apparatus 118 can be sequentially subjected to the steps shown in FIGS. 2 to 7 or FIGS. 2 and 3 and 16 to 18, like the semiconductor apparatus 100.

As described above, the steps shown in FIGS. 16 to 18 curb reduction in a wafer diameter of a semiconductor apparatus. This allows transportation and processing using the same equipment as for a wafer before working.

### [Method for Processing Semiconductor Apparatus According to Modification of Second Embodiment of Present Disclosure]

FIG. 19 is a view showing a modification of the beveling step according to the second embodiment of the present disclosure. A beveling step of the modification works the peripheral portion on the second principal surface side of the thick-film wafer 41 such that a cross-section has a convex structure. This results in obtainment of a thick-film wafer 43a in which an epitaxial film 34a, a peripheral portion of which is uniformly ground, is formed on a divided wafer 20b, a peripheral portion of which is uniformly ground to a fixed depth.

For example, the beveling step of the present modification may be performed on a semiconductor apparatus which has an unbonded region 26, like a semiconductor apparatus 104b. In this case, the unbonded region 26 can be removed by the beveling step.

### Third Embodiment

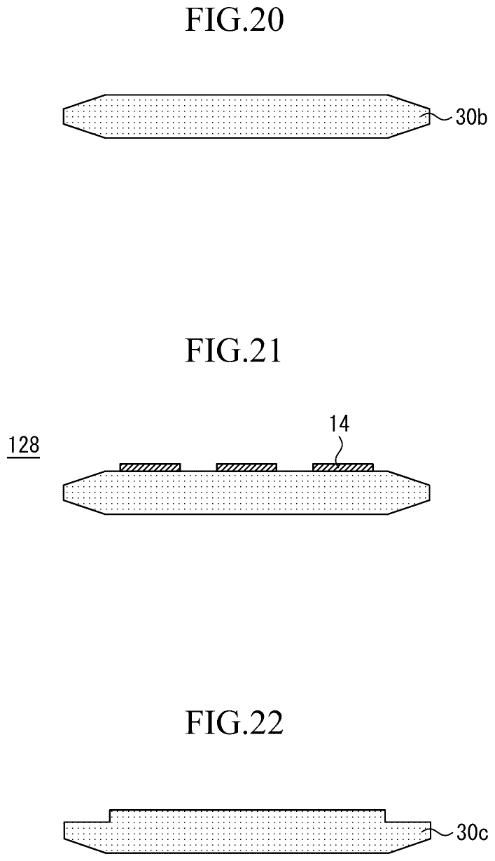

FIG. 20 is a view showing a beveling step according to a third embodiment of the present disclosure. In the first and second embodiments, a beveling step is performed after thickening the whole wafer in order to suppress warpage of the wafer 16. A substrate thickness of a divided wafer according to the present embodiment falls within a range where warpage does not interfere with manufacturing steps. For this reason, the divided wafer is reused without being thickened. This results in reduction in the number of man-hours required for wafer reuse.

In the beveling step of the present embodiment, a peripheral portion on a second principal surface side of a divided wafer is worked into a tapered shape. This results in obtainment of a divided wafer 30b, a peripheral portion on a second principal surface side of which is worked into a tapered shape.

FIG. 21 is a view showing a device formation process according to the third embodiment of the present disclosure. In the device formation process of the present embodiment, an epitaxial film is formed on the second principal surface side of the divided wafer 30b, and a semiconductor device structure 14 is formed on the epitaxial film. Note that the semiconductor device structure 14 is formed inside an outermost peripheral portion of the divided wafer 30b which is tapered.

A semiconductor apparatus 128 obtained in the above-described manner has a similar function to the semiconductor apparatus 100. For this reason, the semiconductor apparatus 128 can be sequentially subjected to the steps shown in FIGS. 2 to 7, like the semiconductor apparatus 100.

As described above, the steps shown in FIGS. 20 and 21 curb reduction in a wafer diameter of a semiconductor apparatus. This allows transportation and processing using the same equipment as for a wafer before working.

FIG. 22 is a view showing a modification of the beveling step according to the third embodiment of the present disclosure. In the beveling step of the modification, a peripheral portion on a second principal surface side of a divided wafer may be worked such that a cross-section has a convex structure. This results in obtainment of a divided wafer 30c, a peripheral portion of which is uniformly ground.

Note that although aspects which bond two divided wafers have been described in the present disclosure, bonding of a plurality of divided wafers is only needed. That is, details of the present disclosure may be applied to an aspect which bonds three or more divided wafers.

Hereinafter, various aspects of the present disclosure will be collectively described as appendixes.

### Appendix 1

A method for manufacturing a semiconductor apparatus, comprising:
a step of forming a semiconductor device structure at a second principal surface of a wafer having a first principal surface and the second principal surface which are opposite from each other;
a step of grinding a peripheral portion of the second principal surface of the wafer, at which the semiconductor device structure is formed, partway in a thickness direction from the second principal surface toward the first principal surface;
a step of dividing the wafer in a direction perpendicular to the thickness direction at a position closer to the second principal surface than a depth to which the peripheral portion of the wafer is ground, and dividing a first divided wafer which does not include the semiconductor device structure from the wafer;
a step of grinding a peripheral portion of a divided surface of the first divided wafer; and
a step of forming a semiconductor device structure on the divided surface of the first divided wafer, the peripheral portion of the divided surface of which is ground.

### Appendix 2

The method for manufacturing a semiconductor apparatus according to appendix 1, further comprising
a step of bonding a second divided wafer to the first principal surface of the first divided wafer.

### Appendix 3

The method for manufacturing a semiconductor apparatus according to appendix 2, wherein
an amorphous layer is formed at a bonding interface between the first divided wafer and the second divided wafer.

### Appendix 4

The method for manufacturing a semiconductor apparatus according to appendix 2 or 3, further comprising
a step of polishing and planarizing a bonding interface of the first divided wafer or the second divided wafer before the bonding, wherein
polishing at a peripheral portion of the bonding interface is performed to a greater extent than polishing at a central portion of the bonding interface.

### Appendix 5

The method for manufacturing a semiconductor apparatus according to any one of appendixes 1 to 4, wherein
a cross-section of the wafer after the grinding the peripheral portion of the second principal surface and before the dividing has a convex structure.

### Appendix 6

The method for manufacturing a semiconductor apparatus according to appendix 5, further comprising
a step of grinding a whole of an outermost peripheral portion of the wafer before the division of the wafer.

### Appendix 7

The method for manufacturing a semiconductor apparatus according to any one of appendixes 1 to 6, wherein
the peripheral portion of the divided surface of the first divided wafer is ground into a tapered shape.

### Appendix 8

The method for manufacturing a semiconductor apparatus according to any one of appendixes 1 to 6, wherein
a cross-section of the wafer after the grinding the peripheral portion of the divided surface of the first divided wafer and before the forming the semiconductor device structure on the divided surface has a convex structure.

### Appendix 9

The method for manufacturing a semiconductor apparatus according to appendix 1, further comprising
a step of forming an epitaxial film on the first divided wafer.

### Appendix 10

The method for manufacturing a semiconductor apparatus according to any one of appendixes 1 to 9, wherein
the wafer is made of a wide bandgap semiconductor.

### Appendix 11

A semiconductor apparatus comprising:
a first divided wafer which has a first principal surface and a second principal surface opposite from each other and has a semiconductor device structure at the second principal surface; and
a second divided wafer which is bonded to the first principal surface of the first divided wafer,
wherein an unbonded region is formed at a peripheral portion of a bonding interface between the first divided wafer and the second divided wafer.

### Appendix 12

The semiconductor apparatus according to appendix 11, wherein
an amorphous layer is formed at the bonding interface.

### Appendix 13

The semiconductor apparatus according to appendix 11 or 12, wherein
a peripheral portion of the first divided wafer is worked into a tapered shape.

### Appendix 14

The semiconductor apparatus according to any one of appendixes 11 to 13, wherein
a wafer diameter of the first divided wafer is smaller than a wafer diameter of the second divided wafer.

### Appendix 15

The semiconductor apparatus according to any one of appendixes 11 to 14, wherein
a cross-section of the second divided wafer has a convex structure, and
an inner diameter of an upper surface of the second divided wafer is the same as an inner diameter of the first divided wafer.

### Appendix 16

A semiconductor apparatus comprising:
a first divided wafer which has a first principal surface and a second principal surface opposite from each other;
an epitaxial film which is formed at the second principal surface of the first divided wafer; and
a semiconductor device structure which is formed on the epitaxial film,
wherein a cross-section of the first divided wafer has a convex structure.

### Appendix 17

The semiconductor apparatus according to appendix 16, wherein
the epitaxial film is 50 μm or more thick.

### Appendix 18

A semiconductor apparatus comprising:
a first divided wafer which has a first principal surface and a second principal surface opposite from each other and has a semiconductor device structure at the second principal surface,
wherein a cross-section of the first divided wafer has a convex structure.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-213137, filed on Dec. 18, 2023 including specification, claims, drawings and summary, on which the Convention priority of the present application is based, are incorporated herein by reference in its entirety.

1. A method for manufacturing a semiconductor apparatus, comprising:
a step of forming a semiconductor device structure at a second principal surface of a wafer having a first principal surface and the second principal surface which are opposite from each other;
a step of grinding a peripheral portion of the second principal surface of the wafer, at which the semiconductor device structure is formed, partway in a thickness direction from the second principal surface toward the first principal surface;
a step of dividing the wafer in a direction perpendicular to the thickness direction at a position closer to the second principal surface than a depth to which the peripheral portion of the wafer is ground, and dividing a first divided wafer which does not include the semiconductor device structure from the wafer;
a step of grinding a peripheral portion of a divided surface of the first divided wafer; and
a step of forming a semiconductor device structure on the divided surface of the first divided wafer, the peripheral portion of the divided surface of which is ground.

2. The method for manufacturing a semiconductor apparatus according to claim 1, further comprising
a step of bonding a second divided wafer to the first principal surface of the first divided wafer.

3. The method for manufacturing a semiconductor apparatus according to claim 2, wherein
an amorphous layer is formed at a bonding interface between the first divided wafer and the second divided wafer.

4. The method for manufacturing a semiconductor apparatus according to claim 2, further comprising
a step of polishing and planarizing a bonding interface of the first divided wafer or the second divided wafer before the bonding, wherein
polishing at a peripheral portion of the bonding interface is performed to a greater extent than polishing at a central portion of the bonding interface.

5. The method for manufacturing a semiconductor apparatus according to claim 1, wherein
a cross-section of the wafer after the grinding the peripheral portion of the second principal surface and before the dividing has a convex structure.

6. The method for manufacturing a semiconductor apparatus according to claim 5, further comprising
a step of grinding a whole of an outermost peripheral portion of the wafer before the division of the wafer.

7. The method for manufacturing a semiconductor apparatus according to claim 1, wherein
the peripheral portion of the divided surface of the first divided wafer is ground into a tapered shape.

8. The method for manufacturing a semiconductor apparatus according to claim 1, wherein
a cross-section of the wafer after the grinding the peripheral portion of the divided surface of the first divided wafer and before the forming the semiconductor device structure on the divided surface has a convex structure.

9. The method for manufacturing a semiconductor apparatus according to claim 1, further comprising
a step of forming an epitaxial film on the first divided wafer.

10. The method for manufacturing a semiconductor apparatus according to claim 1, wherein
the wafer is made of a wide bandgap semiconductor.

11. A semiconductor apparatus comprising:
a first divided wafer which has a first principal surface and a second principal surface opposite from each other and has a semiconductor device structure at the second principal surface; and
a second divided wafer which is bonded to the first principal surface of the first divided wafer,
wherein an unbonded region is formed at a peripheral portion of a bonding interface between the first divided wafer and the second divided wafer.

12. The semiconductor apparatus according to claim 11, wherein
an amorphous layer is formed at the bonding interface.

13. The semiconductor apparatus according to claim 11, wherein
a peripheral portion of the first divided wafer is worked into a tapered shape.

14. The semiconductor apparatus according to claim 11, wherein
a wafer diameter of the first divided wafer is smaller than a wafer diameter of the second divided wafer.

15. The semiconductor apparatus according to claim 11, wherein
a cross-section of the second divided wafer has a convex structure, and
an inner diameter of an upper surface of the second divided wafer is the same as an inner diameter of the first divided wafer.

16. A semiconductor apparatus comprising:
a first divided wafer which has a first principal surface and a second principal surface opposite from each other;
an epitaxial film which is formed at the second principal surface of the first divided wafer; and
a semiconductor device structure which is formed on the epitaxial film, wherein a cross-section of the first divided wafer has a convex structure.

17. The semiconductor apparatus according to claim 16, wherein
the epitaxial film is 50 μm or more thick.

18. A semiconductor apparatus comprising:
a first divided wafer which has a first principal surface and a second principal surface opposite from each other and has a semiconductor device structure at the second principal surface,
wherein a cross-section of the first divided wafer has a convex structure.
